(19) United States
(12) Patent Application Publication
(10) Pub. No.: US 2010/0230280 A1
(43) Pub. Date: Sep. 16, 2010

(54) Self-ionized sputtering apparatus

(75) Inventors: Shinya Nakamura, Susono (JP); Hiroaki Iwasawa, Gotemba (JP); Yoshihiro Ikeda, Mishima (JP)

Correspondence Address: OLIFF & BERRIDGE, PLC, P.O. BOX 320850, ALEXANDRIA, VA, 22320-4850, US

(73) Assignee: ULVAC, INC., Chigasaki-shi (JP)

(21) Appl. No.: 12/659,268

(22) Filed: Mar. 2, 2010

(30) Foreign Application Priority Data
Mar. 12, 2009 (JP) 2009-060155

(51) Int. Cl. C23C 14/34

(52) U.S. Cl. 204/298.08

(57) ABSTRACT

There is provided a low-cost self-sputtering apparatus which is so arranged that, even when an arc discharge occurs for some reasons or other, failure in electric discharge can be prevented. The self-sputtering apparatus has a vacuum chamber in which a substrate to be processed is disposed; a target to be disposed opposite to the substrate; a sputtering power source for charging the target with a negative DC current; an anode shield which is disposed in a manner to enclose a space in front of the target and which is charged with a positive electric potential; and a gas introduction means for introducing a predetermined sputtering gas into the vacuum chamber. The apparatus further has an LC resonance circuit in parallel with an output circuit from the DC power source to the target.

### TECHNICAL FIELD

The present invention relates to a self-ionized sputtering apparatus.

### BACKGROUND ART

For example, in order to form a Cu seed layer at good coverage on micropores of high aspect ratio, there has been used a so-called self-ionized sputtering apparatus (hereinafter also referred to as “a self-sputtering apparatus”). As a conventional self-sputtering apparatus there is known in patent document 1 an apparatus which is made up of: a target of Cu make which is disposed in a manner to lie opposite to a substrate to be processed inside a vacuum chamber; a DC power source (sputtering power source) which charges a negative DC potential to the target; an anode shield which is disposed in a manner to enclose a space in front of the target and which is charged with a positive potential; a gas introducing means which introduces a sputtering gas such as Ar and the like into the vacuum chamber; and a bias power source which charges a bias potential to the substrate.

In the apparatus as described in the above-mentioned patent document 1, at the time of starting the film formation by sputtering, the sputtering gas is introduced into the vacuum chamber through the gas introduction means. In this state, when the target is charged by the DC power source with a predetermined negative potential and also when the anode shield is charged with a positive potential by another DC power source, a glow discharge occurs in the space in front of the sputtering surface of the target. Thereafter, when the introduction of the sputtering gas is stopped by controlling a mass flow controller, a self-discharge will take place in the above-mentioned space under a low pressure. Then, the Ar ions in the plasma will collide onto the sputtering surface of the target, thereby sputtering the target. The Cu atoms are thus scattered and are appropriately reflected by the anode shield. The Cu atoms and ionized Cu ions are emitted from the target toward the substrate, and are drawn with strong linearity toward the substrate that has been charged with a bias potential, thereby getting adhered to, and deposited on, the substrate to form a seed layer made up of Cu.

It is to be noted here that the sputtering power source to be used in a general sputtering apparatus is ordinarily provided with an arc suppression circuit. The output voltage or output current from the DC power source is monitored. If the output voltage or the output current varies and exceeds a predetermined range as a result of occurrence of arc discharge due to some cause or other and consequent change in plasma impedance, a reverse voltage, for example, is charged so that the operation to maintain the electric discharge or the operation of electric re-discharge can be automatically performed.

However, the above-mentioned self-sputtering apparatus has a disadvantage in that, even if the above-mentioned operation is performed after the occurrence of the arc discharge, electric discharge fails because the sputtering gas necessary for maintaining the electric discharge or for the electric re-discharge is not supplied. In such a case, it may be considered to manually or automatically introduce the sputtering gas into the vacuum chamber to thereby perform the operation of electric re-discharge. According to such an arrangement, however, it is impossible to strictly control the sputtering time and therefore a disadvantage will occur in that the yield of products will lower.

On the other hand, it is known in patent document 2 to use a target which is made by mixing with high-purity Cu a material such as Ag and Au having different ionization degrees from that of Cu so that the total contents thereof fall in the range of 0.005˜500 ppm. Plasma is thus stabilized so that electric discharge does not fail. In this kind of target, however, the manufacturing cost thereof becomes higher and, in addition, the manufacturing thereof is troublesome.

[Prior Art Document]

[Patent Document]
[Patent document 1] JP-A-2002-80962
[Patent document 2] JP-A-2001-342560

### SUMMARY OF THE INVENTION

### Problems that the Invention is to Solve

In view of the above-mentioned problems, this invention has a problem of providing a low-cost self-sputtering apparatus in which, even when arc discharge occurs for some reason or other, the electric discharge can be prevented from failing.

### Means for Solving the Problems

In order to solve the above problems, the self-ionized sputtering apparatus according to this invention comprises: a vacuum chamber in which a substrate to be processed is disposed; a target disposed in a manner to lie opposite to the substrate; a sputtering power source for charging the target with negative DC potential; an anode shield which is disposed in a manner to enclose a space in front of the target and which is charged with positive electric potential; a gas introduction means for introducing a predetermined sputtering gas into the vacuum chamber, and an LC resonance circuit disposed in parallel with an output circuit from the DC power source to the target.

According to this invention, in case arc discharge occurs for some reason or other, a sudden voltage drop takes place due to a rapid decrease in a plasma impedance and, accompanied thereby, electric current increases. However, the apparatus has the LC resonance circuit in parallel with the output circuit from the DC power source to the target. Therefore, as a result of resonance of the output current, the output voltage can be prevented from unnecessarily lowering, thereby maintaining the electric discharge.

As described above, according to this invention, only by adding the LC resonance circuit and without the necessity of a special target to which a material different from Cu in ionization degree has been added, the electric discharge can be prevented from failing by a simple construction even when arc discharge has occurred. This arrangement can serve as a low-cost measure against an electric discharge failure.

The self-sputtering apparatus according to this invention preferably further comprises a noise filter on an output circuit from the DC power source to the target so that noise does not enter the output circuit to the target.

### BRIEF DESCRIPTION OF THE DRAWINGS

FIG. 1 is a schematic view explaining a self-ionized sputtering apparatus according to an embodiment of this invention;

FIG. 2 is a figure explaining an output circuit of a sputtering power source for charging a target with a DC potential; and

FIG. 3(a) is a figure showing output waveforms at the time of occurrence of arc discharge in the apparatus of this invention, and FIG. 3(b) is a figure showing output waveforms at the time of occurrence of arc discharge in a conventional apparatus.

### EMBODIMENT FOR CARRYING OUT THE INVENTION

With reference to the accompanying drawings, a description will now be made of a self-ionized sputtering apparatus (hereinafter referred to as “a self-sputtering apparatus”) according to one embodiment of this invention which is suitable for forming a seed layer made of Cu.

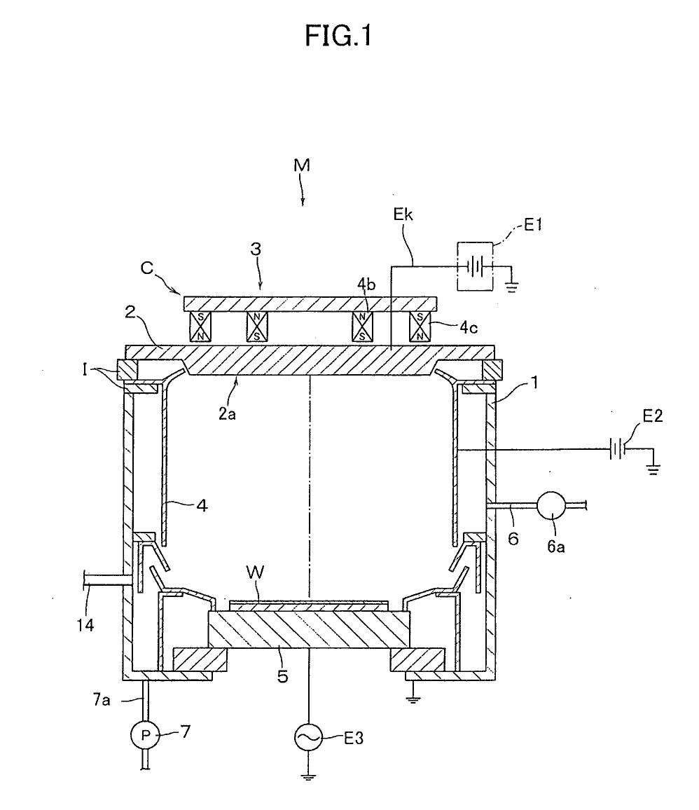

As shown in FIG. 1, a self-sputtering apparatus M has a vacuum chamber 1 which is capable of forming therein a vacuum atmosphere. On a ceiling portion of the vacuum chamber 1 there is mounted a cathode unit C. In the following description the direction to look toward the ceiling side of the vacuum chamber 1 is defined as a “top or upper side” and the direction to look toward the bottom side thereof is defined as a “bottom or lower side.”

The cathode unit C is made up of a target 2, and a magnet unit 3 which is disposed on the upper side of the target 2. The target 2 can be made in a known method of a material, e.g., such as Ti or Ta other than Cu, that is appropriately selected depending on the composition of a thin film that is going to be formed on a substrate W to be processed. The target 2 is mounted on the vacuum chamber 1 through an insulating body I in a state in which the target is attached to a backing plate (not illustrated). The magnet unit 3, on the other hand, has a known structure which serves to generate a magnetic field in a space below a sputtering surface 2a of the target 2, and to arrest the electrons and the like ionized below the sputtering surface 2a at the time of sputtering, thereby efficiently ionizing the sputtered particles scattered from the target 2. Detailed description of the magnet unit is, therefore, omitted here. The target 2 is connected to a DC power source E1 which is the sputtering power source and, during sputtering, is charged with a negative DC potential.

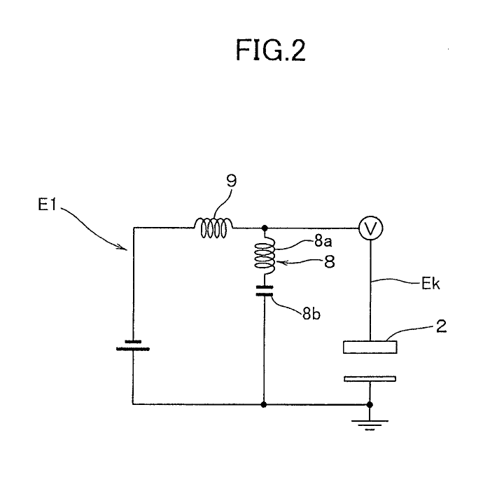

The DC power source E1 is of a known construction having an arc suppression circuit, and has the following arrangement, i.e., it monitors the voltage or current of the output Ek that leads from the DC power source E1 to the target 2 (see FIG. 2). If the output voltage or the output current varies and exceeds a predetermined range as a result of occurrence of an arc discharge for some reason or other with a consequent change in the plasma impedance, a reverse voltage, for example, is charged so that the operation to maintain the electric discharge or the operation of electric re-discharge can be automatically performed.

The vacuum chamber 1 has disposed therein an anode shield 4 having electrical conductivity. The anode shield 4 is a tubular member which is elongated downward toward the bottom side while covering the circumference of the target 2. The anode shield 4 is connected to another DC power source E2 and is charged, during sputtering, with a positive DC potential. By means of this anode shield 4 the ions of the ionized sputtered particles are reflected so as to assist them to be discharged toward the substrate W with a strong linearity.

At the bottom of the vacuum chamber 1 there is disposed a stage 5 in a manner to lie opposite to the cathode unit C so that the substrate W to be processed such as a silicon wafer and the like can be held in position. The stage 5 is connected to a high-frequency power source E3 so that, during sputtering, a bias potential can be charged to the stage 5 and consequently to the substrate W. The ions, particularly of the sputtered particles, are positively drawn to the substrate W.

To a side wall of the vacuum chamber 1 there is connected a gas pipe 6 to introduce a sputtering gas which is an inert gas such as argon and the like. This gas pipe 6 is communicated with a gas source (not illustrated) through a mass flow controller 6a. These parts constitute a gas introduction means and, therefore, the sputtering gas whose flow rate is controlled can be introduced into the vacuum chamber 1. Further, to the bottom of the vacuum chamber 1 there is connected an evacuation pipe 7a which is in communication with an evacuation apparatus 7 made up of a turbo molecular pump, a rotary pump, and the like. The above-mentioned self-sputtering apparatus M has a known control means (not illustrated) which is provided with a microcomputer, a sequencer, and the like. It is thus so arranged that the operation of each of the above-mentioned DC power source and the high-frequency power sources E1 through E3, the operation of the mass flow controller 6a, the operation of the evacuation apparatus 7, and the like can be central-controlled by the control means.

As the substrate W to be processed by the above-mentioned self-sputtering apparatus M, there is used one which, after having formed a silicon oxide film (insulating film) on the surface of a Si wafer, has formed micropores, in the silicon oxide film, for wiring by means of patterning of a known method. A description will now be made of the operation in an example in which a Cu film as a seed layer is formed on the substrate W by the above-mentioned self-sputtering apparatus M.

After having mounted the substrate W on the stage 5 which lies opposite to the cathode unit C, the evacuation means 7 is operated to evacuate the vacuum chamber 1 to a predetermined vacuum degree (e.g., 10⁻⁵ Pa). When the pressure inside the vacuum chamber 1 has reached a predetermined value, the mass flow controller 6a is controlled to introduce Ar gas into the vacuum chamber 1 at a predetermined flow rate. Then, the anode shield 4 is charged with a positive potential (e.g., 100 V) by the DC power source E2, the target 2 is charged with a negative potential (e.g., −500 V) by the DC power source E1, and the substrate W is charged with a negative bias potential (e.g., making power 300 W) by the high-frequency power source E3.

According to the above arrangement, a glow discharge will occur in a space which is below the sputtering surface 2a and which is enclosed by the anode shield 4, and the plasma is contained by the magnetic field generated by the magnet unit 3. Thereafter, when the introduction of the sputtering gas is stopped by controlling the mass flow controller 6a, self discharge occurs in the above-mentioned space under low pressure.

In this state the argon ions and the like in the plasma collide onto the sputtering surface 2a of the target 2, whereby the target is sputtered. The Cu atoms are thus scattered and the Cu atoms and the ionized Cu ions are emitted with strong linearity toward the substrate W while being appropriately reflected by the anode shield 4. By charging the substrate with bias potential, the sputtered particles and the ions of the sputtered particles are positively drawn substantially at right angles to the substrate W, thereby being adhered to, and deposited on, the substrate.

By the way, in the above-mentioned self-sputtering apparatus M, the introduction of the sputtering gas is stopped during self discharge. Therefore, even if the arc discharge may occur and the operation of maintaining the discharge or the operation of electric re-discharge may be performed on the part of the DC power source E1, the required sputtering gas is not available. Therefore, it is necessary to see that discharge does not fail.

To attain the above, in this embodiment, as shown in FIG. 2, there is provided an LC resonance circuit 8 in parallel with an output circuit which is made up, in the sputtering power source E (E1), of an output Ek to the target 2 and a ground potential. In this case, as a coil 8a to constitute the LC resonance circuit 8, there may be used one of 5˜200 μH and, as a capacitor 8b, there may be used one of 0.10˜0.44 μF. Further, in the output Ek to the target 2 there is provided a noise filter 9 which is made up, e.g., of a coil so that noise does not enter the power circuit. In this case, as the coil of the noise filter 9, there is used one of 0.7 μH˜5 mH. As shown in FIG. 2, a voltmeter (an ammeter) is connected to the output (line) to the target so that the output current (or the output voltage) can be measured.

By employing the above-mentioned arrangement, in case an arc discharge has occurred for some reason or other, a sudden voltage drop may occur due to a sudden decrease in the plasma impedance and, accompanied thereby, the current increases. However, as a result of having provided the LC resonance circuit 8, the output current resonates, thereby preventing the output voltage from unnecessarily dropping. As a consequence, glow discharge comes to be maintained. Accordingly, only by adding the LC resonance circuit 8, there is required no special target that has added thereto, like in the conventional art, a material such as Ag, Au and the like which is different from Cu in ionization degrees. Failure in electric discharge can thus be prevented by a simple construction.

In order to confirm the effect of the above, there was formed a Cu film with the self-sputtering apparatus M (according to this invention) in which the DC power source E1 was used as shown in FIG. 2. As the substrate W, there was used one which, after having formed a silicon oxide film over the entire surface of a Si wafer of Φ300 mm, has formed by patterning micropores (40 nm in width, 140 nm in depth) in the silicon oxide film according to the known method. As the cathode material, on the other hand, there was used one which was made of Cu of composition ratio of 99.9999% and was formed into a thickness of 12 mm.

As the film-forming conditions, the distance between the sputtering surface 2a of the target 2 and the substrate W was set to 300 mm. And setting of the making power to the target 2 was made to 16 kW (current 38 A), of the making voltage to the anode shield 8 was made to 100 V, of the bias power was made to 300 W, and of the sputtering time was made to 30 seconds, respectively, whereby a Cu film was formed. Then, by using Ar as the sputtering gas, the sputtering gas was introduced at a flow rate of 10 sccm for 3 seconds at the beginning of film forming by sputtering. As a comparative experiment, there was used a DC power source without an LC resonance circuit (conventional apparatus).

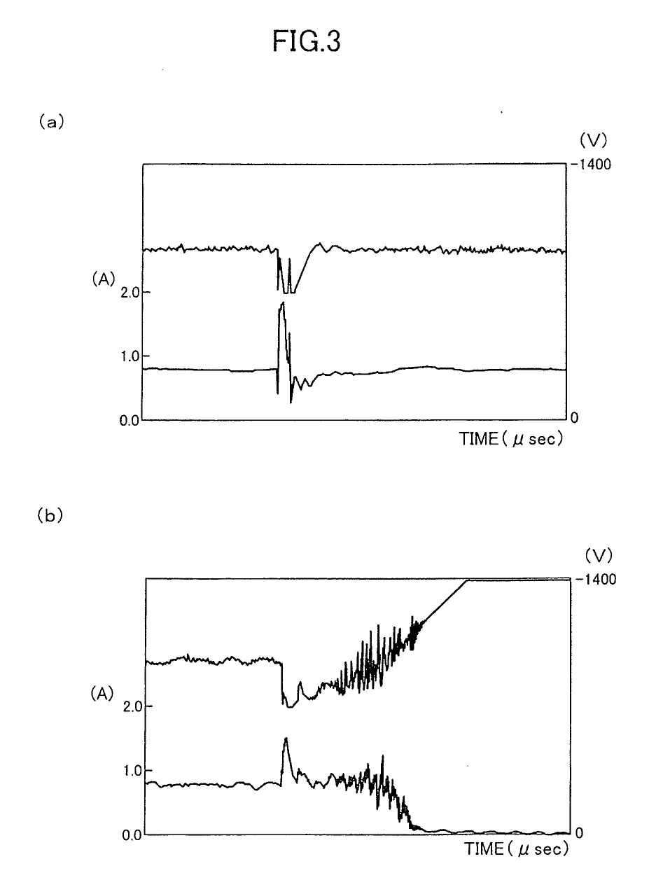

Description will now be made with reference to FIG. 3. It can be seen that in the conventional apparatus, when arc discharge occurs, the output voltage suddenly drops and, accompanied by this, that the output current suddenly increases, thereby bringing about a failure in the electric discharge (see FIG. 3(b)). In the apparatus of this invention, on the other hand, it can be seen that, although the output voltage drops at the beginning of the occurrence of the arc discharge, the output voltage drop can be suppressed as a result of resonance of the output current, thereby maintaining the electric discharge (see FIG. 3(a)).

Although description has so far been made of the self-sputtering apparatus M according to the embodiment of this invention, this invention is not limited to the above-mentioned embodiment. For example, in the above-mentioned embodiment, a description was made of an example in which one sputtering power source E1 was used. This invention can, however, be applied to an example in which the power source apparatus is constituted by connecting a slave power source to a master power source. In such a case, the above-mentioned LC resonance circuit is provided in the respective power sources.

### EXPLANATION OF REFERENCE NUMERALS

M self-ionized sputtering apparatus
1 vacuum chamber
2 target
4 anode shield
6 gas pipe (gas introduction means)
8 LC resonance circuit
9 noise filter
E1 DC power source (sputtering power source)
Ek output
W substrate

1. A self-ionized sputtering apparatus comprising:
a vacuum chamber having disposed therein a substrate to be processed and a target lying opposite to the substrate;
a sputtering power source for charging the target with a negative DC potential;
an anode shield which is disposed in a manner to enclose a space in front of the target and which is charged with a positive electric potential; and
a gas introduction means which introduces a predetermined sputtering gas into the vacuum chamber,
wherein the appartus has an LC resonance circuit in parallel with an output circuit from the sputtering power source to the target.

2. The sputtering apparatus according to claim 1, further comprising a noise filter disposed on the output from the sputtering power source to the target.

3. The sputtering apparatus according to claim 1, wherein the target becomes depleted by use of the apparatus, and is replenishable.
